(19) United States
(12) Patent Application Publication
(10) Pub. No.: US 2025/0194342 A1
(43) Pub. Date: Jun. 12, 2025

(54) ARRAY SUBSTRATE, DISPLAY PANEL, AND DISPLAY DEVICE

(71) Applicants: Hefei Visionox Technology Co., Ltd., Hefei (CN); Visionox Technology Inc., Kunshan (CN)

(72) Inventors: Zhiwei ZHOU, Hefei (CN); Jinfang ZHANG, Hefei (CN); Lu ZHANG, Hefei (CN)

(73) Assignees: Hefei Visionox Technology Co., Ltd., Hefei (CN); Visionox Technology Inc., Kunshan (CN)

(21) Appl. No.: 19/059,309

(22) Filed: Feb. 21, 2025

(30) Foreign Application Priority Data
Mar. 4, 2024 (CN) 202410246200.9

(51) Int. Cl. H10K 59/121; H10K 59/131

(52) U.S. Cl. CPC H10K 59/1213; H10K 59/131

(57) ABSTRACT

Embodiments of the present application provide an array substrate and a display panel. The array substrate includes: a substrate; and a driving device layer disposed on a side of the substrate, the driving device layer including a plurality of driving units, where the array substrate has at least a light-transmitting area, an orthographic projection of the light-transmitting area on the substrate being located between orthographic projections of two of the driving units on the substrate. In the embodiments of the present application, the influence of the provision of the light-transmitting area on the wiring in the driving unit can be reduced, and the wiring structure of the array substrate can be simplified. Moreover, the metal wiring area between two adjacent driving units is small, and the distribution area of the light-transmitting area can be increased, and the light transmittance of the array substrate can be increased.

### CROSS REFERENCE TO RELATED APPLICATION

The present application claims priority to Chinese Patent Application No. 202410246200.9 filed on Mar. 4, 2024, which is incorporated herein by reference in its entirety.

### FIELD

The present application relates to the field of display apparatuses, and in particular to an array substrate, a display panel and a display device.

### BACKGROUND

Organic light emitting diode (OLED) and flat panel display devices based on technologies such as light emitting diode (LED) have been widely applied to various consumer electronics such as mobile phones, televisions, notebook computers and desktop computers and predominate in display devices thanks to their advantages such as high image quality, energy efficiency, slim design and a wide range of applications.

However, the process performance of conventional OLED display products needs to be improved.

### SUMMARY

Embodiments of the present application provide an array substrate, a display panel and a display device, with the aim of improving the process performance of the display panel.

An embodiment of the present application provides an array substrate, including: a substrate; and a driving device layer disposed on a side of the substrate, the driving device layer including a plurality of driving units, wherein the array substrate has at least a light-transmitting area, an orthographic projection of the light-transmitting area on the substrate being located between orthographic projections of two of the driving units on the substrate.

According to any one of the above embodiments of the present application, the at least a light-transmitting area comprise a plurality of light-transmitting areas, and each first orthographic projection is located between the orthographic projections of the driving transistors of two of the driving units on the substrate.

According to any one of the above embodiments of the present application, the array substrate further includes a first electrode layer, the first electrode layer including a plurality of first electrodes distributed in an array, the driving unit being electrically connected to the first electrode.

According to any one of the above embodiments of the present application, the orthographic projections of the two driving transistors on the substrate are respectively located on opposite sides of the first orthographic projection in a first direction;
the connecting wire includes a first segment and two inclined segments connected to two ends of the first segment, the first segments of two connecting wires being disposed on two sides of the light-transmitting area in the first direction, and the first segment extending in a second direction which intersects the first direction; and orthographic projections, on the substrate, of the two inclined segments connected to the first segment in the second direction are obliquely disposed in a direction close to the first orthographic projection.

According to any one of the above embodiments of the present application, the connecting wire further includes a second segment extending in the second direction, the two inclined segments include a first inclined segment, the first inclined segment being located between the first segment and the second segment, and the first segment is electrically connected to the first reset transistor via the second segment.

According to any one of the above embodiments of the present application, a side of the second segment facing away from the first inclined segment is further connected to a third segment, where the third segment is configured to extend in the first direction, the third segments of the two driving units located on two sides of the light-transmitting area extend from respective second segments in directions away from each other, and an end of the third segment facing away from the second segment is electrically connected to the first reset transistor.

According to any one of the above embodiments of the present application, the connecting wire further includes a fourth segment extending in the first direction, the two inclined segments further include a second inclined segment connected between the first segment and the fourth segment, and the fourth segment is electrically connected to the driving transistor.

According to any one of the above embodiments of the present application, the first bent portion includes a first section and second sections, where an orthographic projection of the first section on the substrate is located on a side, which faces away from the first orthographic projection, of an orthographic projection of the first extension portion on the substrate, the two second sections are respectively connected to two ends of the first section, the second section is connected to the first section and the first extension portion, and part of the first orthographic projection is located between orthographic projections of the two second sections on the substrate.

According to any one of the above embodiments of the present application, the first extension portion and the first bent portion are alternately connected to each other in the first direction.

An embodiment of the present application further provides an array substrate, including: a substrate; and a driving device layer disposed on one side of the substrate, the driving device layer including a first signal line and a second signal line, where an orthographic projection of the first signal line on the substrate and an orthographic projection of the second signal line on the substrate are both configured to extend in a first direction, and the orthographic projection of the first signal line on the substrate and the orthographic projection of the second signal line on the substrate are disposed side by side in a second direction which intersects the first direction; where the array substrate includes at least a light-transmitting area, an orthographic projection of the light-transmitting area on the substrate being defined as a first orthographic projection located between the orthographic projection of the first signal line on the substrate and the orthographic projection of the second signal line on the substrate.

An embodiment of the present application further provides a display panel, including the array substrate of any one of the above embodiments, where the display panel further includes a functional layer located on a side of the driving device layer facing away from the substrate, one or more light-transmitting holes being provided in the functional layer, and an orthographic projection of the light-transmitting hole on the substrate at least partially overlapping with the orthographic projection of the corresponding light-transmitting area on the substrate.

According to an embodiment of the present application, the display panel further includes a light-emitting layer located between the driving device layer and the functional layer, where the light-emitting layer includes a light-emitting unit, and the functional layer is further provided with a filter hole in which a filter unit is provided, an orthographic projection of the filter unit on the substrate at least partially overlapping with an orthographic projection of the light-emitting unit on the substrate.

An embodiment of a third aspect of the present application further provides a display device, including the display panel of any one of the above embodiments of the first aspect.

In the array substrate according to the embodiments of the present application, the array substrate includes a substrate and a driving device layer, the driving device layer including a plurality of driving units. When the array substrate is used in a display panel, a single driving unit is configured to drive a single sub-pixel of the display panel for display. The metal wiring in the driving unit is generally dense. In the embodiments of the present application, the light-transmitting area is disposed between the orthographic projections of two adjacent driving units on the substrate, and the influence of the provision of the light-transmitting area on the wiring in the driving unit can be reduced, and the wiring structure of the array substrate can be simplified. Moreover, the metal wiring area between two adjacent driving units is small, and the distribution area of the light-transmitting area can be increased, and the light transmittance of the array substrate can be increased. When the array substrate is used in a display panel, the light transmittance of the display panel can be increased, thereby improving the process performance of the display panel.

### BRIEF DESCRIPTION OF THE DRAWINGS

Other features, objects, and advantages of the present application will become more apparent upon reading the following detailed description of non-limiting embodiments with reference to the accompanying drawings, in which identical or similar reference signs indicate identical or similar features.

FIG. 1 is a schematic structural diagram of an array substrate according to an embodiment of the present application;

FIG. 2 is a schematic structural diagram of a cross section along line A-A in FIG. 1;

FIG. 3 is a schematic structural diagram of a circuit of a driving unit of an array substrate according to an embodiment of the present application;

FIG. 4 is a schematic structural diagram of film layers of an array substrate according to an embodiment of the present application;

FIG. 5 is a schematic structural diagram of one of the film layers in FIG. 4;

FIG. 6 is a schematic structural diagram of another one of the film layers in FIG. 4;

FIG. 7 is a schematic structural diagram of two of the film layers in FIG. 4;

FIG. 8 is a schematic structural diagram of one of the film layers in FIG. 7;

FIG. 9 is a schematic structural diagram of the other film layer in FIG. 7;

FIG. 10 is a timing diagram of a driving unit of an array substrate according to an embodiment of the present application;

FIG. 11 is a schematic structural diagram of a display panel according to an embodiment of the present application;

FIG. 12 is a schematic structural diagram of a cross section along line B-B in FIG. 11; and

FIG. 13 is a schematic structural diagram of a display device according to an embodiment of the present application.

### LIST OF REFERENCE SIGNS

10. array substrate; 20. display panel;
100. substrate;
200. driving device layer;
210. driving unit; T1. driving transistor; T2. data write transistor; T3. threshold compensation transistor; T4. first reset transistor; T5. first light emission control transistor; T6. second light emission control transistor; T7. second reset transistor; T8. bias transistor; 211. semiconductor layer; 211a. source region; 211b. drain region; 211c. channel region;
220. first signal line; 221. first extension portion; 222. first bent portion; 222a. first section; 222b. second section;
230. second signal line;
240. connecting wire; 241. first segment; 242. inclined segment; 242a. first inclined segment; 242b. second inclined segment; 243. second segment; 244. third segment; 245. fourth segment;
250. third signal line; 251. second extension portion; 252. second bent portion;
300. first electrode layer; 310. first electrode;
400. pixel defining layer; 410. pixel defining portion; 420. pixel opening; 430. light-emitting unit;
500. second electrode layer;
600. encapsulation layer;
700. functional layer; 720. light-transmitting hole; 730. filter unit; 740. light shielding portion;
TA. light-transmitting area; X. first direction; Y. second direction.

### DETAILED DESCRIPTION OF EMBODIMENTS

The features and exemplary embodiments of various aspects of the present application will be described in detail below. In the following detailed description, numerous specific details are set forth in order to provide a complete understanding of the present application. It will be apparent to those skilled in the art, however, that the present application may be embodied without some of these specific details. The following description of the embodiments is merely to provide a better understanding of the present application by illustrating examples of the present application. In the accompanying drawings and the following description, at least some well-known structures and techniques are not shown in order to avoid unnecessary obscuring of the present application; and the dimensions of some structures may be exaggerated for clarity. In addition, the features, structures, or characteristics described below may be combined in one or more embodiments in any suitable manner.

In the description of the present application, it should be noted that “a plurality of” means two or more, unless otherwise specified. The orientation or position relationship indicated by the terms “upper”, “lower”, “left”, “right”, “inner”, “outer”, etc. is only for the convenience of describing the present application and simplifying the description, rather than indicating or implying that the device or element referred to must have a particular orientation or be constructed and operated in a particular orientation, and therefore should not be construed as a limitation on the present application. Moreover, the terms “first”, “second”, etc. are merely used for the illustrative purpose, and should not be construed as indicating or implying relative importance.

The orientation terms in the following description all indicate directions shown in the accompanying drawings, and do not limit the specific structure in the embodiments of present application. In the description of the present application, it should be noted that, the terms “mount” and “connect” should be interpreted in a broad sense unless explicitly defined and limited otherwise. For example, they may be a fixed connection, a detachable connection an integral connection; or may refer to a direct connection, or an indirect connection. For those of ordinary skill in the art, the specific meanings of the terms mentioned above in the present application can be construed according to specific circumstances.

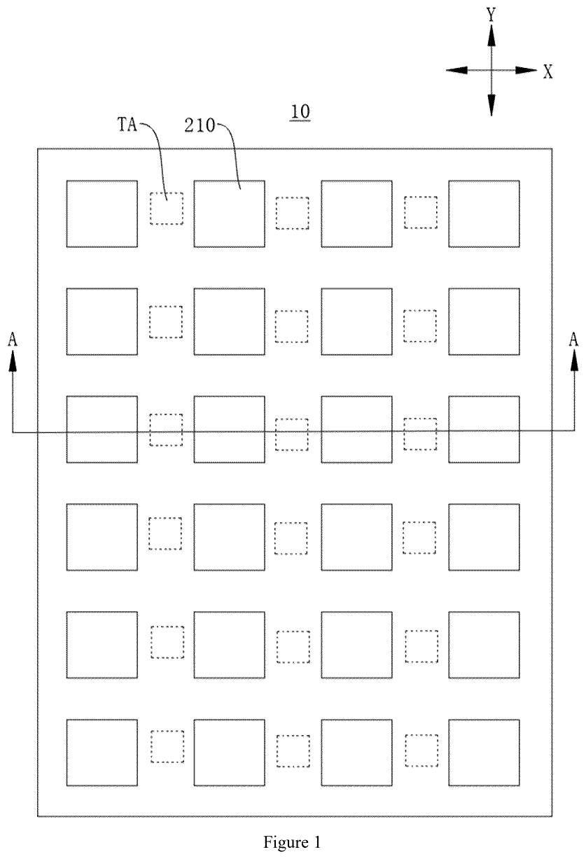

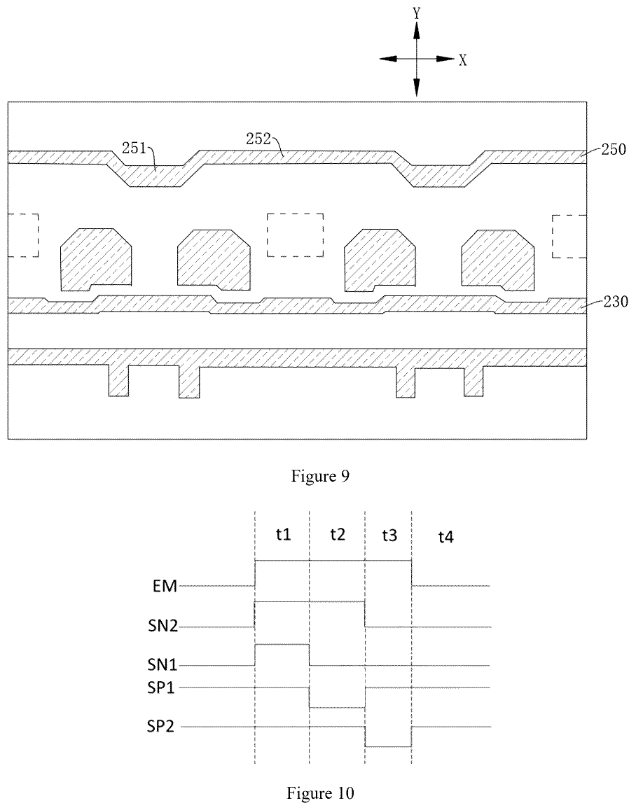

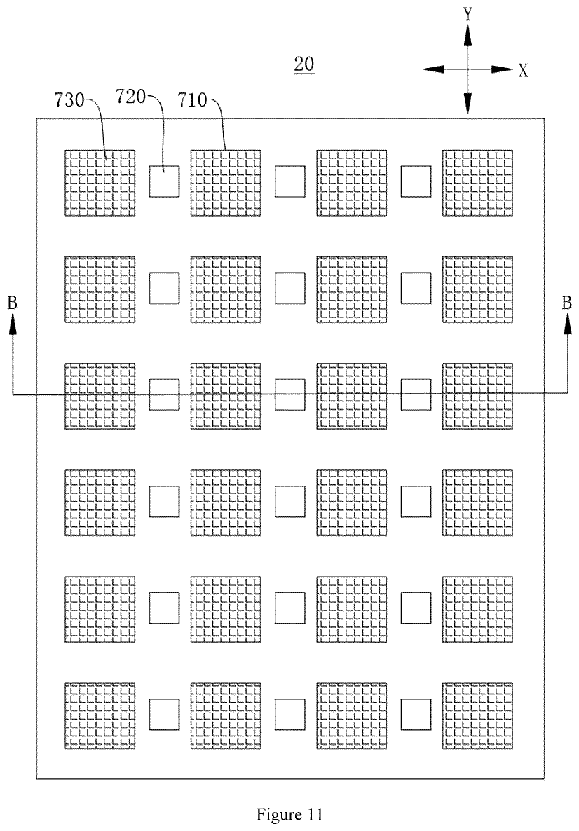

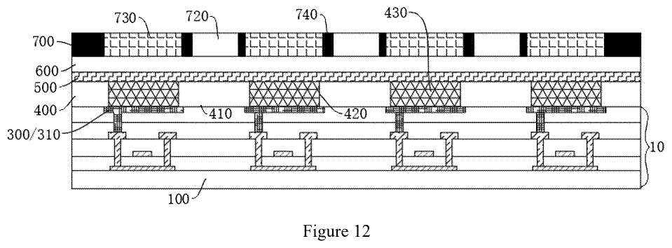

In order to better understand the present application, an array substrate, a display panel and a display device in embodiments of the present application will be described in detail below with reference to FIGS. 1 to 12.

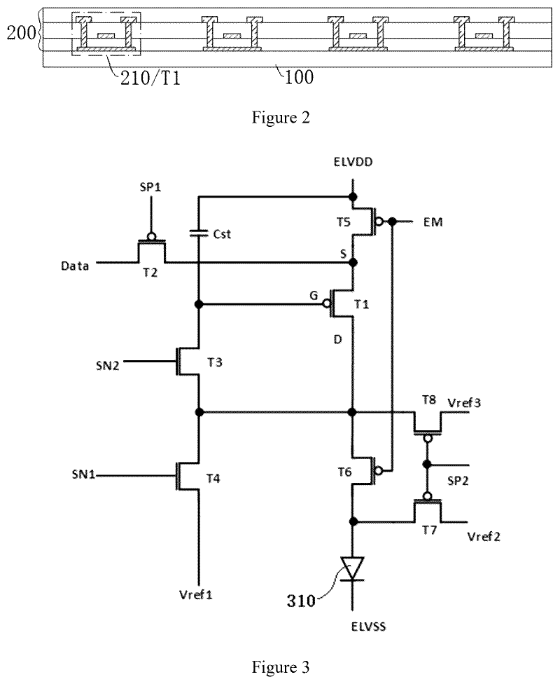

Referring to FIGS. 1 and 2 together, FIG. 1 is a schematic structural diagram of an array substrate 10 according to an embodiment of the present application, and FIG. 2 is a schematic structural diagram of a cross section along line A-A in FIG. 1.

As shown in FIGS. 1 and 2, an embodiment of the present application provides an array substrate 10. The array substrate 10 includes a substrate 100 and a driving device layer 200. The driving device layer 200 is disposed on one side of the substrate 100, and the driving device layer 200 includes a plurality of driving units 210. The array substrate 10 has at least a light-transmitting area TA. An orthographic projection of the light-transmitting area TA on the substrate 100 is defined as a first orthographic projection located between orthographic projections of two of the driving units 210 on the substrate 100.

In the array substrate 10 according to the embodiments of the present application, the array substrate 10 includes a substrate 100 and a driving device layer 200, the driving device layer 200 including a plurality of driving units 210. When the array substrate 10 is used in a display panel, a single driving unit 210 is configured to drive a single sub-pixel of the display panel for display. Of course, in other embodiments, a single driving unit 210 may be configured to drive a plurality of sub-pixels of the display panel for display. The metal wiring in the driving unit 210 is generally dense. The first orthographic projection is located between the orthographic projections of the two driving units 210 on the substrate 100, that is, the light-transmitting area TA is correspondingly disposed between the orthographic projections of the two adjacent driving units 210 on the substrate 100, and it is possible to reduce the influence of the light-transmitting area TA on the wiring in the driving unit 210, and simplify the wiring structure of the array substrate 10. Moreover, the metal wiring area between two adjacent driving units 210 is small, and the distribution area of the light-transmitting area TA can be increased, and the light transmittance of the array substrate 10 can be increased. When the array substrate 10 is used in a display panel, the light transmittance of the display panel can be increased, thereby improving the process performance of the display panel.

In one embodiment, the substrate 100 may be a flexible substrate 100 or a rigid substrate 100.

In one embodiment, the driving unit 210 may include a plurality of thin film transistors and at least one of capacitor. The driving unit 210 may be any one of a 2T1C circuit, a 7T1C circuit, a 7T2C circuit, an 8T1C circuit, and a 9T1C circuit. In the embodiments of the present application, “2T1C circuit” is a pixel circuit in which the driving unit 210 includes two thin film transistors (T) and one capacitor (C), and the same applies to the “7T1C circuit”, the “7T2C circuit,” the “8T1C circuit”, the “9T1C circuit”, etc. The driving unit 210 may further include a different number of thin film transistors and a different number of capacitors as long as the driving unit 210 can drive the sub-pixel for display when the array substrate 10 is used in a display panel.

In one embodiment, the light-transmitting area TA is a partial area of the array substrate 10 as indicated by a dashed line in FIG. 1, and the light-transmitting area TA does not constitute a structural limitation on the array substrate 10 of the embodiments of the present application.

In some embodiments, as shown in FIGS. 1 to 4, the driving unit 210 includes a driving transistor T1. At least one first orthographic projection is located between orthographic projections of driving transistors T1 of two driving units 210 on the substrate 100.

The driving unit 210 includes a plurality of thin film transistors. For example, the driving unit 210 includes a data write transistor T2, a first reset transistor T4, and a driving transistor T1. The distribution area of the driving transistor T1 is generally large, and the space on the peripheral side of the driving transistor T1 is large. In the embodiments of the present application, the first orthographic projection is disposed within the orthographic projections of the driving transistors T1 of two adjacent driving units 210 on the substrate 100, and it is possible to accommodate the light-transmitting area TA by using a large gap between the two adjacent driving transistors T1, and to increase the distribution area of the light-transmitting area TA.

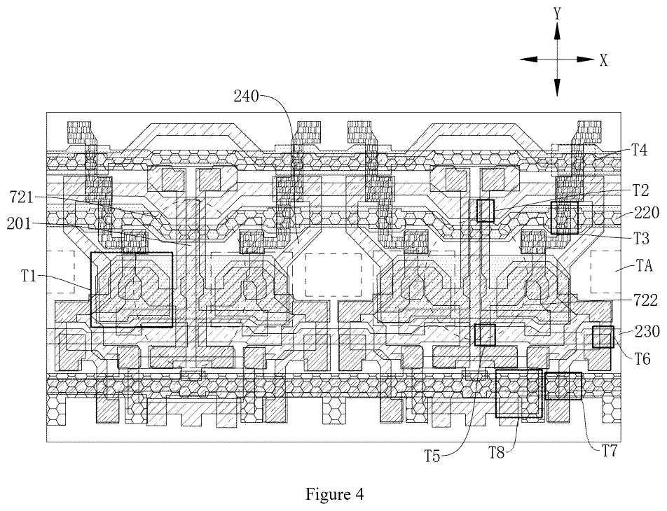

In one embodiment, taking the 8T1C circuit as an example, still referring to FIG. 3, the thin film transistors of the driving unit 210 further include a threshold compensation transistor T3, a bias transistor T8, a first light emission control transistor T5, a second light emission control transistor T6 and a second reset transistor T7. The thin film transistors and the capacitor of the driving unit 210 are connected in the manner shown in FIG. 3, and the positions of the thin film transistors are indicated by frame lines in FIG. 4.

In other embodiments, as described above, the driving unit 210 may be any one of a 2T1C circuit, a 7T1C circuit, a 7T2C circuit, and a 9T1C circuit. Other thin film transistors may also be included in the driving unit 210, and the thin film transistors of the driving unit 210 may be electrically connected to each other in other manners.

In some embodiments, the at least a light-transmitting area comprise a plurality of light-transmitting areas TA are provided, to further increase the light transmittance of the array substrate 10. In one embodiment, one of light-transmitting area TA is located between orthographic projections of driving transistors T1 of two driving units 210 on the substrate 100. In one embodiment, one of light-transmitting area TA is located between orthographic projections of driving transistors T1 of two adjacent driving units 210 on the substrate 100. For example, a first orthographic projection is disposed between the orthographic projections of the driving transistors T1 of the two adjacent driving units 210 on the substrate 100, to further increase the overall light transmittance of the array substrate 10.

In one embodiment, the at least a light-transmitting area comprise a plurality of light-transmitting areas TA, and each first orthographic projection is located between orthographic projections of driving transistors T1 of two driving units 210 on the substrate 100, to further increase the overall light transmittance of the array substrate 10. When the array substrate is used in a display panel, the display panel includes a first display area and a second display area. The first display area is a light-transmissive and displayable area for disposing a photosensitive element. For example, the first display area is configured to allow for disposing an infrared sensing element, a fingerprint recognition element, etc. The second display area may be a main display area disposed around at least part of the first display area, and the light-transmitting area TA may be located in the first display area to improve the light transmittance of the first display area, to facilitate infrared sensing, fingerprint recognition and other functions. In one embodiment, with reference to FIGS. 4-12, the array substrate 10 further includes a first electrode layer 300. The first electrode layer 300 includes a plurality of first electrodes 310 disposed in an array. The driving transistor T1 is electrically connected to the first electrode 310. In the embodiments of the present application, the driving transistor T1 is a thin film transistor electrically connected to the first electrode 310, and the driving transistor T1 is connected to the first electrode 310 to send a signal to the first electrode 310.

In one embodiment, the driving transistors T1 are distributed spaced apart from each other in the first direction X. The first orthographic projection is disposed between the orthographic projections, on the substrate 100, of two driving transistors T1 adjacent to each other in the first direction X, and the distribution area of the light-transmitting area TA can be further increased.

In one embodiment, at least two driving transistors T1 are respectively located on two sides of the light-transmitting area TA in the first direction X.

In one embodiment, the symmetrical distribution of the driving transistors T1 located on two sides of the light-transmitting area TA in the first direction X can simplify the metal wiring structure of the driving device layer 200 while also ensuring that the characteristics of each driving transistor are the same, thereby ensuring the display effect.

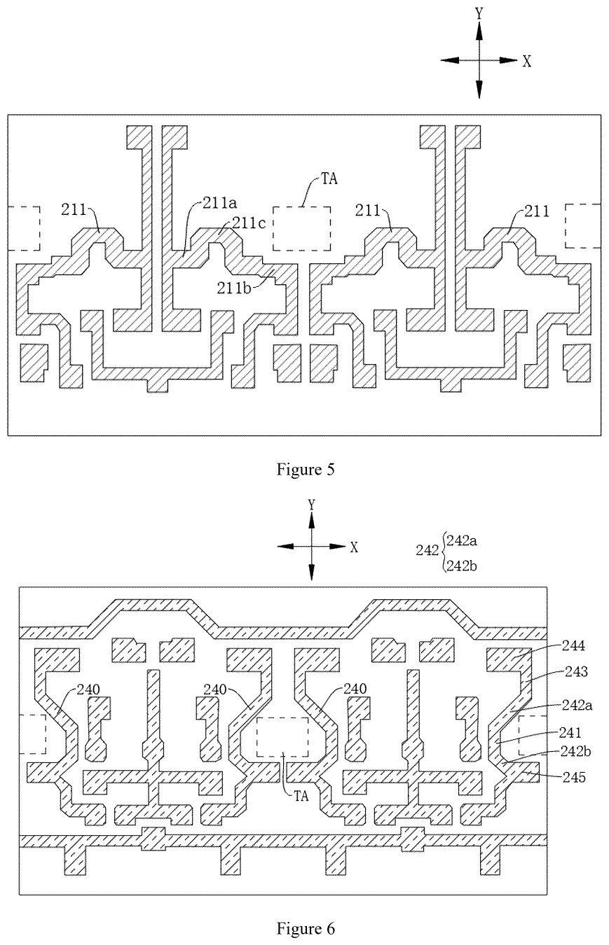

In some embodiments, as shown in FIGS. 4 and 5, the driving transistor T1 includes a semiconductor layer 211. The semiconductor layer 211 includes a source region 211a, a drain region 211b, and a channel region 211c located between the source region 211a and the drain region 211b. The channel region 211c is configured to protrude with respect to the source region 211a and the drain region 211b in the second direction Y. Assuming that the semiconductor layer 211 is generally I-shaped, on the basis of ensuring the performance of the driving transistor T1, the extension dimension of the semiconductor layer 211 in the first direction X can be reduced, thereby increasing the spacing between two driving transistors T1 adjacent to each other in the first direction X, and increasing the distribution area of the light-transmitting area TA. In some specific embodiments, the first direction X is perpendicular to the second direction Y.

In one embodiment, the driving device layer 200 further includes a second signal line 230. An orthographic projection of the second signal line 230 on the substrate 100 is configured to extend in the first direction X. In one embodiment, the second signal line 230 may be located on one side, in the second direction Y, of a plurality of driving transistors T1, which are located in the same row and arranged in the first direction X.

In one embodiment, an orthographic projection of the channel region 21 icon the substrate 100 protrudes in a direction away from the orthographic projection of the second signal line 230 on the substrate 100, to make the layout of the semiconductor layer 211 more scientific and reasonable.

In one embodiment, the orthographic projection of the drain region 211b on the substrate 100 is located between the orthographic projection of the source region 211a on the substrate 100 and the first orthographic projection, and in the second direction Y, a distance between the orthographic projection of the source region 211a on the substrate 100 and the orthographic projection of the second signal line 230 on the substrate 100 is greater than a distance between the orthographic projection of the drain region 211b on the substrate 100 and the orthographic projection of the second signal line 230 on the substrate 100. Of course, in some embodiments, the orthographic projections of the two driving transistors T1 on the substrate 100 are respectively located on opposite sides of the first orthographic projection in the first direction X, and the distance between the orthographic projection of the source region 211a of at least one of the driving transistors T1 on the substrate 100 and the orthographic projection of the second signal line 230 on the substrate 100 in the second direction Y is greater than the distance between the orthographic projection of the drain region 211b on the substrate 100 and the orthographic projection of the second signal line 230 on the substrate 100 in the second direction Y. That is, it is possible to define the source region 211a and the drain region 211b of only one of the driving transistors T1, to increase the distribution area of the light-transmitting hole 710.

In the above embodiment, the drain region 211b is closer to the light-transmitting area TA than the source region 211a, and the distance between the drain region 211b and the second signal line 230 is shorter, and the drain region 211b can provide clearance for the light-transmitting area TA, further increasing the distribution area of the light-transmitting area TA.

In one embodiment, the orthographic projections, on the substrate 100, of the semiconductor layers 211 of the driving transistors T1 located on two sides of the same light-transmitting area TA are symmetrically distributed about the first orthographic projection. For example, the orthographic projections, on the substrate 100, of the semiconductor layers 211 of the driving transistors T1 located on the two sides of the same light-transmitting area TA are symmetrically distributed about a first reference line where the geometric center of the first orthographic projection is located. When the first orthographic projection is a circle, the orthographic projections, on the substrate 100, of the semiconductor layers 211 of the driving transistors T1 located on two sides of the same light-transmitting area TA are symmetrically distributed about the first reference line which extends in the second direction Y and passes through the center of the circle of the first orthographic projection, to simplify the wiring structure of the driving device layer 200. In one embodiment, when the first orthographic projection is a rectangle, the first reference line extends in the second direction Y and passes through the intersection of the diagonals of the first orthographic projection to simplify the wiring structure of the driving device layer 200. In this case, the second direction Y is perpendicular to the first direction X.

In some embodiments, with reference to FIGS. 3, 4 and 6, the driving unit 210 further includes a first reset transistor T4 and a connecting wire 240. The driving transistor T1 is connected to the first reset transistor T4 via the connecting wire 240, and an orthographic projection of the connecting wire 240 on the substrate 100 surrounds part of the first orthographic projection.

In these embodiments, the driving unit 210 further include a first reset transistor T4. The first reset transistor T4 may reset a gate of the driving transistor T1. The first reset transistor T4 and the driving transistor T1 are connected to each other via the connecting wire 240, and the orthographic projection of the connecting wire 240 on the substrate 100 surrounds part of the first orthographic projection, and the connecting wire 240 can provide clearance for the light-transmitting area TA, further increasing the distribution area of the light-transmitting area TA.

In one embodiment, the orthographic projection of the connecting wire 240 on the substrate 100 is configured to be bent in a direction away from the first orthographic projection, to further provide clearance for the light-transmitting area TA to increase the distribution area of the light-transmitting area TA.

In one embodiment, connecting wires 240 of the driving units 210 located on the two sides of the light-transmitting area TA in the first direction X are symmetrically distributed to simplify the wiring structure in the driving device layer 200.

The connecting wire 240 may be shaped in a variety of ways. For example, the connecting wire 240 may extend along an arc-shaped path, and the shape of the connecting wire 240 fits the shape of the edge of the light-transmitting area TA.

In some other embodiments, referring to FIG. 6, two driving transistors T1 are respectively disposed on two sides of the light-transmitting area TA in the first direction X, and the connecting wire 240 includes a first segment 241 and two inclined segments 242 connected to two ends of the first segment 241. First segments 241 of two connecting wires 240 are respectively disposed on the two sides of the light-transmitting area TA in the first direction X. The first segment 241 extends in the second direction Y, and orthographic projections, on the substrate 100, of the two inclined segments 242 extending away from the first segment 241 in the second direction Y are disposed obliquely in a direction close to the first orthographic projection.

In these embodiments, the connecting wire 240 includes a first segment 241 and two inclined segments 242, and the inclined segments 242 can provide clearance for the wiring which is located at the orthographic projections of the inclined segments on the substrate 100 and on the side facing away from the first orthographic projection, and the shape of the connecting wire 240 can better fit the shape of the light-transmitting area TA. The first segment 241 and the two inclined segments 242 can be configured to extend in a straight line to facilitate the manufacturing and formation of the connecting wire 240.

In one embodiment, the connecting wire 240 further includes a second segment 243 extending in the second direction Y, the two inclined segments 242 include a first inclined segment 242a, the first inclined segment 242a being connected between the first segment 241 and the second segment 243, and the first segment 241 is electrically connected to the first reset transistor T4 via the second segment 243.

In these embodiments, the second segment 243 is provided on a side of the first inclined segment 242a facing away from the first segment 241, and the length of the connecting wire 240 can be increased, facilitating the electrical connection of the connecting wire 240 to the first reset transistor T4.

In one embodiment, a side of the second segment 243 facing away from the first inclined segment 242a is further connected to a third segment 244. The third segment 244 is configured to extend in the first direction X, and third segments 244 of two connecting wires 240 located on two sides of the light-transmitting area TA extend from respective second segments 243 in directions away from each other. An end of the third segment 244 facing away from the second segment 243 is electrically connected to the first reset transistor T4. By adding the third segment 244, the length of the connecting wire 240 can be further increased, facilitating the electrical connection of the connecting wire 240 to the first reset transistor T4.

In one embodiment, the connecting wire 240 further includes a fourth segment 245 extending in the first direction X, and the two inclined segments 242 further include a second inclined segment 242b connected between the first segment 241 and the fourth segment 245. The fourth segment 245 is electrically connected to the driving transistor T1. By adding the fourth segment 245, the orthographic projection of the connecting wire 240 on the substrate 100 can better surround the first orthographic projection and the length of the connecting wire 240 is increased, facilitating the electrical connection of the connecting wire 240 to the driving transistor T1.

In some embodiments, as shown in FIGS. 4 and 7 to 9, the driving device layer 200 further includes a first signal line 220 and a second signal line 230. An orthographic projection of the first signal line 220 on the substrate 100 and an orthographic projection of the second signal line 230 on the substrate 100 are both configured to extend in the first direction X, and the orthographic projection of the first signal line 220 on the substrate 100 and the orthographic projection of the second signal line 230 on the substrate 100 are disposed side by side in the second direction Y. The first orthographic projection is located between the orthographic projection of the first signal line 220 on the substrate 100 and the orthographic projection of the second signal line 230 on the substrate 100.

In these embodiments, the first orthographic projection may be located between the first signal line 220 and the second signal line 230 adjacent to each other, to reduce the influence of the first signal line 220 and the second signal line 230 on the light transmittance of the light-transmitting area TA.

In one embodiment, driving units 210 disposed in the same row in the first direction X are connected to the same first signal line 220 and the same second signal line 230, the first orthographic projection is located between the orthographic projections, on the substrate 100, of two driving units 210 adjacent to each other in the first direction X, and the first orthographic projection is located between the orthographic projection of the adjacent first signal line 220 on the substrate 100 and the orthographic projection of the second signal line 230 on the substrate 100, and the distribution area of the light-transmitting area TA can be further increased.

In one embodiment, orthographic projections of driving transistors T1 on the substrate 100 are located between the orthographic projection of the adjacent first signal line 220 on the substrate 100 and the orthographic projection of the second signal line 230 on the substrate 100, and the driving transistors T1 are distributed spaced apart from each other in the first direction X. In one embodiment, the first orthographic projection is located between the orthographic projections, on the substrate 100, of driving transistors T1 of two driving units 210 adjacent to each other in the first direction X, and the first orthographic projection is located between the orthographic projection of the adjacent first signal line 220 on the substrate 100 and the orthographic projection of the second signal line 230 on the substrate 100, and the distribution area of the light-transmitting area TA can be further increased.

In one embodiment, the number of first signal lines 220 and the number of second signal lines 230 are both two or more. The first signal line 220 and the second signal line 230 and the driving units 210 disposed in the same row are connected to each other, that is, the first signal line 220, the second signal line 230 and the driving units 210 disposed in the same row are correspondingly disposed, and the orthographic projection of the light-transmitting area TA on the substrate 100 is located between the orthographic projection of the first signal line 220 on the substrate 100 and the orthographic projection of the second signal line 230 on the substrate 100, the first signal line 220 and the second signal line 230 being adjacent to each other and connected to the driving units 210 disposed in the same row.

The first signal line 220 and the second signal line 230 may be located in the same film layer or in different film layers. For example, the first signal line 220 and the second signal line 230 are located in different film layers, to reduce the distribution area of the wiring in the same film layer. When lines located in different film layers are electrically connected, the connection can be made through vias.

In one embodiment, the first signal line 220 is a scanning signal line and the second signal line 230 is a light emission control signal line. A large gap between the scanning signal line and the light emission control signal line which are connected to the driving units 210 in the same row can increase the distribution area of the light-transmitting area TA.

In one embodiment, the driving unit 210 includes a threshold compensation transistor T3. The threshold compensation transistor T3 is electrically connected to the first signal line 220. That is, the first signal line 220 is a scanning signal line connected to the threshold compensation transistor T3, and a gap between the scanning signal line and the light emission control signal line is large, and the distribution area of the light-transmitting area TA can be increased.

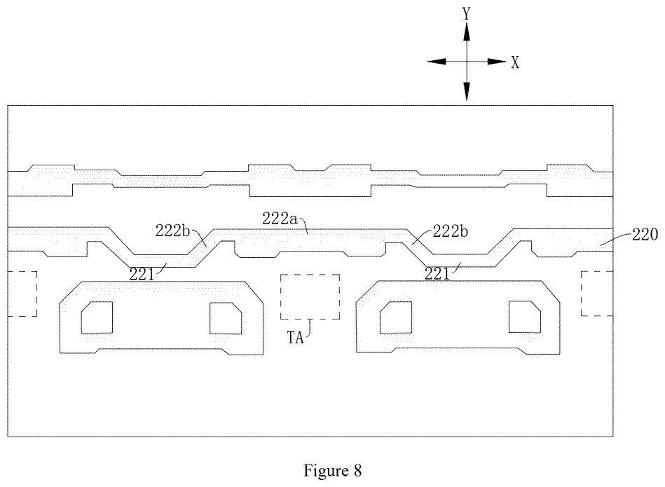

In one embodiment, the driving device layer 200 further includes a voltage reference line Vref, a power supply signal line ELVDD, a low-level power supply signal line ELVSS, and a data line Data. The driving device layer 200 includes a first scanning signal line SN1 and a second scanning signal line SN2. The first scanning signal line SN1 is electrically connected to the first reset transistor T4 shown in FIG. 3 to control the switching of the first reset transistor T4. The second scanning signal line SN2 is electrically connected to the threshold compensation transistor T3, and the second scanning signal line SN2 is configured to control the switching of the threshold compensation transistor T3. The first signal line 220 described above may be the second scanning signal line SN2. Referring to FIG. 8, the first scanning signal line SN1 is disposed in the same layer as the second scanning signal line SN2, and the first scanning signal line SN1 is configured to extend in the first direction. The first scanning signal line SN1 is located on a side of the second scanning signal line SN2 away from a light-transmitting area TA, which is not marked in the figures.

In one embodiment, as shown in FIG. 3, the light emission control signal line EM is connected to the first light emission control transistor T5 and the second light emission control transistor T6.

In one embodiment, as shown in FIGS. 3 and 10, the driving device layer 200 further includes a third scanning signal line SP1 and a fourth scanning signal line SP2. The voltage reference line Vref includes a first voltage reference line Vref1, a second voltage reference line Vref2 and a third voltage reference line Vref3. However, the array substrate is used in a display panel, and during the light-emitting operation of the display panel, in stages t1 to t3, the light emission control signal line EM is at a high level, the first light emission control transistor T5 and the second light emission control transistor T6 are in a closed state, a signal of the driving power supply voltage signal line ELVDD does not enter the first electrode 310, and the sub-pixel does not emit light. In stages t1 and t2, the second scanning signal line SN2 is at a high level, the threshold compensation transistor T3 is turned on, and the gate G and a drain D of the driving transistor T1 are connected. Moreover, in stage t1, the first scanning signal line SN1 is at a high level, the first reset transistor T4 is turned on, the first voltage reference signal line Vref1 is connected to the gate G of the driving transistor T1, to reset the gate G of the driving transistor T1. In stage t2, the third scanning signal line SP1 is at a low level, the data write transistor T2 is turned on, and the data line Data is connected to the data write transistor T2, a source S and the drain D of the driving transistor T1 and the gate G of the driving transistor T1. In stage t3, the fourth scanning signal line SP2 is at a low level, the second reset transistor T7 and the bias transistor T8 are turned on, the second voltage reference signal line Vref2 is connected to the first electrode 310, and the third voltage reference signal line Vref3 is connected to the drain D of the driving transistor T1. In stage t4, the light emission control signal line EM is at a low level, the first light emission control transistor T5 and the second light emission control transistor T6 are in a turned-on state, the driving power supply voltage signal line ELVDD is connected to the first electrode 310, and the sub-pixel emits light. In some embodiments, the bias transistor T8 may be two thin film transistors connected in series, which can reduce leakage current.

The first signal line 220 may be shaped in a variety of ways. For example, the first signal line 220 extends rectilinearly in the first direction X.

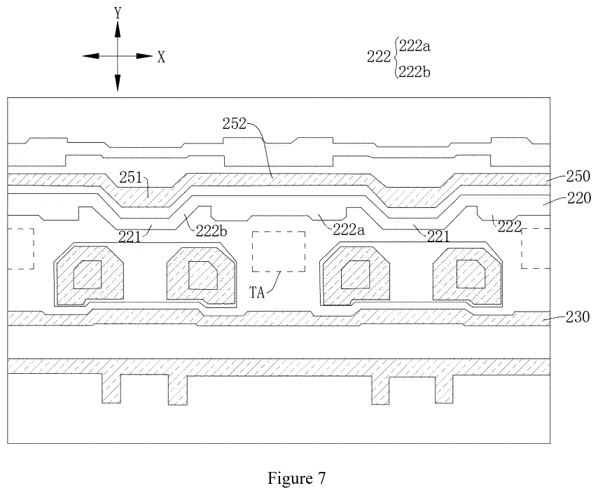

In one embodiment, in some other embodiments, referring to FIG. 7 or 8, the first signal line 220 includes a first extension portion 221 and a first bent portion 222 connected to each other. An orthographic projection of the first bent portion 222 on the substrate 100 is located on one side of the first orthographic projection, and the orthographic projection of the first bent portion 222 on the substrate 100 is configured to protrude in the direction away from the first orthographic projection.

In these embodiments, the orthographic projection of the first bent portion 222 on the substrate 100 is configured to protrude in the direction away from the first orthographic projection with respect to an orthographic projection of the first extension portion 221 on the substrate 100, and the first bent portion 222 can provide clearance for the light-transmitting area TA to further increase the distribution area of the light-transmitting area TA.

In one embodiment, the first bent portion 222 includes a first section 222a and second sections 222b. An orthographic projection of the first section 222a on the substrate 100 is located on a side, which faces away from the first orthographic projection, of the orthographic projection of the first extension portion 221 on the substrate 100. The two second sections 222b are connected to two ends of the first section 222a, and the second section 222b is connected to the first section 222a and the first extension portion 221. Part of the first orthographic projection is located between the orthographic projections of the two second sections 222b on the substrate 100.

In these embodiments, the first bent portion 222 includes the first section 222a and the second sections 222b, the two second sections 222b being connected to two sides of the first section 222a, the first bent portion 222 protrudes in a generally trapezoidal shape, and part of the first orthographic projection is located between the orthographic projections of the two second sections 222b on the substrate 100, and the first bent portion 222 can better provide clearance for the light-transmitting area TA to further increase the area of the light-transmitting area TA.

In one embodiment, the first extension portion 221 and the first bent portion 222 are alternately connected to each other in the first direction X. When there are light-transmitting areas TA, first bent portions 222 can provide clearance for the light-transmitting areas TA.

In some embodiments, the driving device layer 200 further includes a third signal line 250. An orthographic projection of the third signal line 250 on the substrate 100 is located on a side, which faces away from the light-transmitting area TA, of the orthographic projection of the first signal line 220 on the substrate 100, and the third signal line 250 includes a second extension portion 251 and a second bent portion 252 connected to each other. An orthographic projection of the second bent portion 252 on the substrate 100 is located on a side, which faces away from the first orthographic projection, of the orthographic projection of the first bent portion 222 on the substrate 100, and the orthographic projection of the second bent portion 252 on the substrate 100 is configured to protrude in the direction away from the first orthographic projection.

In the embodiments of the present application, the shape of the third signal line 250 located on a side, which faces away from the first orthographic projection, of the orthographic projection of the first signal line 220 on the substrate 100 fits the shape of the first signal line 220, and it is possible to improve the problem of the first signal line 220 and the third signal line 250 being likely to be short-circuited due to their overlap.

In one embodiment, an orthographic projection of the second extension portion 251 on the substrate 100 is disposed parallel to the orthographic projection of the first extension portion 221 on the substrate 100, and/or the orthographic projection of the first bent portion 222 on the substrate 100 is disposed equidistantly from the orthographic projection of the second bent portion 252 on the substrate 100, and the shape of the first signal line 220 better fits the shape of the third signal line 250.

In one embodiment, the third signal line 250 and the first signal line 220 are located in different film layers. When the third signal line 250 and the first signal line 220 are located in different film layers, the spacing between the third signal line 250 and the first signal line 220 can be minimized, thereby improving the problem of too large spacing due to the limitation of the manufacturing process caused by the third signal line 250 and the first signal line 220 being located in the same layer, and the first signal line 220 can be as close to the third signal line 250 as possible to provide clearance for the light-transmitting area TA.

In one embodiment, the third signal line 250 and the second signal line 230 are located in the same film layer. In this way, the third signal line 250 and second signal line 230 can be manufactured and formed in the same process step, and the manufacturing process of the display panel can be simplified.

In one embodiment, the driving unit 210 includes a data write transistor T2. The third signal line 250 is electrically connected to the data write transistor T2. In other embodiments, the third signal line 250 may also be another signal line.

Referring to FIGS. 1 to 9 together, an embodiment of the present application further provides an array substrate 10, the array substrate 10 including a substrate 100 and a driving device layer 200. The driving device layer 200 is disposed on one side of the substrate 100. The driving device layer 200 includes a first signal line 220 and a second signal line 230. An orthographic projection of the first signal line 220 on the substrate 100 and an orthographic projection of the second signal line 230 on the substrate 100 are both configured to extend in the first direction X, and the orthographic projection of the first signal line 220 on the substrate 100 and the orthographic projection of the second signal line 230 on the substrate 100 are disposed side by side in the second direction Y. The array substrate 10 includes a light-transmitting area TA. An orthographic projection of the light-transmitting area TA on the substrate 100 is defined as a first orthographic projection, the first signal line 220 is a scanning signal line, the second signal line 230 is a light emission control signal line, and the first orthographic projection is located between the first signal line 220 and the second signal line 230.

In the embodiment of the present application, the light-transmitting area TA is correspondingly located between the first signal line 220 and the second signal line 230, and the first signal line 220 and the second signal line 230 can provide clearance for the light-transmitting area TA, increasing the distribution area of the light-transmitting area TA.

In one embodiment, the first signal line 220 is a scanning signal line and the second signal line 230 is a light emission control signal line. The light-transmitting area TA is located between the scanning signal line and the light emission control signal line, and the scanning signal line and the light emission control signal line can provide clearance for the light-transmitting area TA, increasing the distribution area of the light-transmitting area TA.

In some embodiments, the driving device layer 200 further includes a driving unit 210, the first signal line 220 and the second signal line 230 are electrically connected to the same driving unit 210, and the first orthographic projection is located between orthographic projections, on the substrate 100, of the first signal line 220 and the second signal line 230 which are electrically connected to the same driving unit 210. For example, driving units 210 disposed in the same row in the first direction X are electrically connected to the same first signal line 220 and the same second signal line 230, the first orthographic projection is located between two driving units 210 adjacent to each other in the first direction X, and the first orthographic projection is located between the orthographic projection of the adjacent first signal line 220 on the substrate 100 and the orthographic projection of the second signal line 230 on the substrate 100, to further increase the distribution area of the light-transmitting area TA.

In some embodiments, the first signal line 220 includes a first extension portion 221 and a first bent portion 222. An orthographic projection of the first bent portion 222 on the substrate 100 is located on one side of the first orthographic projection in the second direction Y, and the orthographic projection of the first bent portion 222 on the substrate 100 is configured to protrude in the direction away from the first orthographic projection with respect to an orthographic projection of the first extension portion 221 on the substrate 100.

In these embodiments, the first bent portion 222 can provide clearance for the light-transmitting area TA to further increase the distribution area of the light-transmitting area TA.

In one embodiment, the array substrate 10 includes light-transmitting areas TA. An orthographic projection of each light-transmitting area TA on the substrate 100 is located between the corresponding orthographic projections, on the substrate 100, of the first signal line 220 and the second signal line 230 which are electrically connected to the same driving unit 210. That is, the light-transmitting area TA is disposed corresponding to the first signal line 220 and the second signal line 230. The light-transmitting areas TA can further increase the light transmittance of the array substrate 10.

In some embodiments, the driving device layer 200 further includes a third signal line 250. An orthographic projection of the third signal line 250 on the substrate 100 is located on a side, which faces away from the first orthographic projection, of the orthographic projection of the first signal line 220 on the substrate 100, and the third signal line 250 includes a second extension portion 251 and a second bent portion 252 connected to each other. An orthographic projection of the second bent portion 252 on the substrate 100 is located on a side, which faces away from the first orthographic projection, of the orthographic projection of the first bent portion 222 on the substrate 100, and the orthographic projection of the second bent portion 252 on the substrate 100 is configured to protrude in the direction away from the first orthographic projection.

In the embodiments of the present application, the shape of the third signal line 250 fits the shape of the first signal line 220, and it is possible to improve the problem of the first signal line 220 and the third signal line 250 being likely to be short-circuited due to their overlap.

In one embodiment, the first signal line 220, the second signal line 230, the third signal line 250 and the driving unit 210 are disposed in the same manner as above, which will not be described in detail here.

Referring to FIGS. 1 to 12 together, an embodiment of a second aspect of the present application further provides a display panel, including the array substrate 10 of any one of the above embodiments of the first aspect. The display panel further includes a functional layer 700 located on a side of the driving device layer 200 facing away from the substrate 100. One or more light-transmitting holes 720 are provided in the functional layer 700. An orthographic projection of the light-transmitting hole 720 on the substrate 100 at least partially overlaps with the orthographic projection of the corresponding light-transmitting area TA on the substrate 100.

In these embodiments, the orthographic projection of the light-transmitting hole 720 on the substrate 100 is at least partially located within the orthographic projection of the light-transmitting area TA on the substrate 100, and in the array substrate 10 of any one of the above embodiments of the first aspect, the distribution area of the light-transmitting area TA is large, and the distribution area of the light-transmitting hole 710 can be set to be large, thereby increasing the overall light transmittance of the display panel.

In one embodiment, the light-transmitting hole 720 is configured to transmit ambient light, there may be light-transmitting holes 720, and each light-transmitting area TA is disposed corresponding to a light-transmitting hole 720, to further increase the light transmittance of the display panel.

In some embodiments, the display panel further includes a light-emitting layer located between the driving device layer 200 and the functional layer 700. The light-emitting layer includes a light-emitting unit 430, and the functional layer 700 is further provided with a filter hole in which a filter unit 730 is disposed. An orthographic projection of the filter unit 730 on the substrate 100 at least partially overlaps with an orthographic projection of the light-emitting unit 430 on the substrate 100.

In these embodiments, the functional layer 700 includes the filter hole and the light-transmitting hole 720 which are provided in a light shielding portion 740, the filter unit 730 being disposed in the filter hole. By providing the light-transmitting hole 720 in the functional layer 700, the influence of the part of the light shielding portion 740 between two adjacent filter holes on the light transmittance of the display panel can be reduced. The orthographic projection of the filter unit 730 on the substrate 100 is configured to at least partially overlap with the orthographic projection of the light-emitting unit 430 on the substrate 100, and the filter unit 730 can filter stray light emitted by the light-emitting unit 430 to improve the display effect of the display panel.

In one embodiment, the display panel further includes a pixel defining layer 400. The pixel defining layer 400 is located on a side of the first electrode layer 300 facing away from the substrate, and the pixel defining layer 400 includes a pixel defining portion 410 and a pixel opening 420. The light-emitting unit 430 is located in the pixel opening 420. In one embodiment, the display panel further includes a second electrode layer 500. The second electrode layer 500 is located on a side of the pixel defining layer 400 facing away from the substrate, and the second electrode layer 500 and the first electrode 310 interact to drive the light-emitting unit 430 to emit light. In one embodiment, an encapsulation layer 600 is further provided on a side of the second electrode layer 500 facing away from the substrate. The encapsulation layer 600 is configured to provide sealing protection for the light-emitting unit 430. In one embodiment, the functional layer 700 is located on a side of the encapsulation layer 600 facing away from the substrate, and other film layers such as a touch layer may be provided between the functional layer 700 and the encapsulation layer 600.

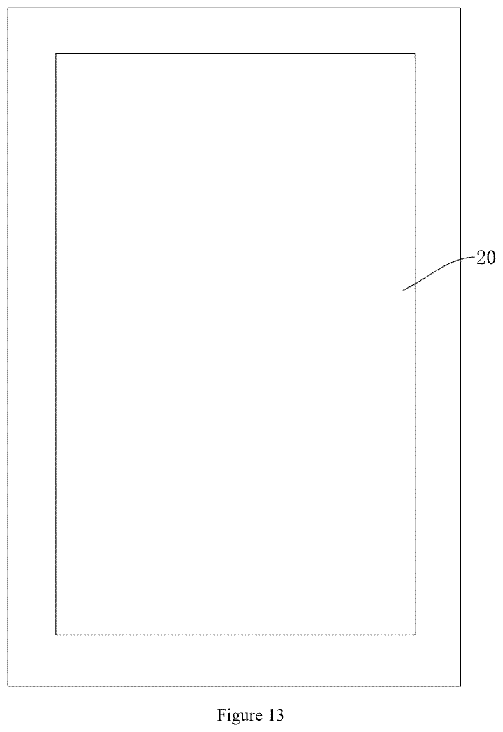

As shown in FIG. 13, an embodiment of a third aspect of the present application further provides a display device, including the display panel 20 of any one of the above embodiments of the first aspect. Since the display device according to the embodiment of the present application includes the display panel 20 of any one of the above embodiments of the first aspect, the display device according to the embodiment of the present application has the beneficial effects of the display panel 20 of any one of the above embodiments of the first aspect, and will not be described in detail here.

The display device in the embodiments of the present application includes, but is not limited to, a cell phone, a personal digital assistant (PDA), a tablet computer, an e-book, a television, an access control system, a smart landline phone, a console, and other devices having a display function.

Although the present application has been described with reference to the embodiments, various modifications can be made, and equivalents can be provided to substitute for the components thereof without departing from the scope of the present application. In particular, the features mentioned in the embodiments can be combined in any manner, provided that there is no structural conflict. The present application is not limited to the specific examples disclosed herein but includes all the embodiments that fall within the scope of the claims.

What is claimed is:

1. An array substrate, comprising:
a substrate; and
a driving device layer disposed on a side of the substrate, the driving device layer comprising a plurality of driving units,
wherein the array substrate has at least a light-transmitting area, an orthographic projection of the light-transmitting area on the substrate being defined as a first orthographic projection located between orthographic projections of two of the driving units on the substrate.

2. The array substrate according to claim 1, wherein the driving unit comprises a driving transistor, and the first orthographic projection is located between orthographic projections of the driving transistors of the two driving units on the substrate; and
the at least a light-transmitting area comprise a plurality of light-transmitting areas, and one of the first orthographic projection is located between the orthographic projections of the driving transistors of the two driving units on the substrate.

3. The array substrate according to claim 2, wherein the orthographic projections of the two driving transistors on the substrate are respectively located on opposite sides of the first orthographic projection in a first direction.

4. The array substrate according to claim 3, wherein the driving transistors located on the two sides of the first orthographic projection in the first direction are symmetrically distributed.

5. The array substrate according to claim 3, wherein the driving transistor comprises a semiconductor layer, the semiconductor layer comprising a source region, a drain region, and a channel region located between the source region and the drain region, wherein the channel region is configured to protrude with respect to the source region and the drain region in a second direction which intersects the first direction;
an orthographic projection of the channel region on the substrate protrudes in a direction away from an orthographic projection of a second signal line on the substrate, the second signal line being configured to extend in the first direction, and the second signal line being electrically connected to the driving unit; and
an orthographic projection of the drain region on the substrate is located between an orthographic projection of the source region on the substrate and the first orthographic projection.

6. The array substrate according to claim 5, wherein the orthographic projections of the two driving transistors on the substrate are respectively located on the opposite sides of the first orthographic projection in the first direction, and a distance between the orthographic projection of the source region of at least one of the driving transistors on the substrate and the orthographic projection of the second signal line on the substrate in the second direction is greater than a distance between the orthographic projection of the drain region on the substrate and the orthographic projection of the second signal line on the substrate in the second direction; and
the second signal line is a light emission control signal line.

7. The array substrate according to claim 2, wherein the driving unit further comprises a first reset transistor and a connecting wire, the driving transistor is connected to the first reset transistor via the connecting wire, and an orthographic projection of the connecting wire on the substrate surrounds part of the first orthographic projection.

8. The array substrate according to claim 7, wherein the orthographic projection of the connecting wire on the substrate is configured to be bent in a direction away from the first orthographic projection; and
the connecting wires of the driving units located on two sides of the light-transmitting area are symmetrically distributed.

9. The array substrate according to claim 1, wherein the driving device layer further comprises a first signal line and a second signal line, wherein an orthographic projection of the first signal line on the substrate and an orthographic projection of the second signal line on the substrate both extend in a first direction, and the orthographic projection of the first signal line on the substrate and the orthographic projection of the second signal line on the substrate are disposed side by side in a second direction which intersects the first direction; and
the first orthographic projection is located between the orthographic projection of the first signal line on the substrate and the orthographic projection of the second signal line on the substrate.

10. The array substrate according to claim 9, wherein a plurality of driving units disposed in the same row in the first direction are connected to the same first signal line and the same second signal line, the first orthographic projection is located between the orthographic projections, on the substrate, of two driving units adjacent to each other in the first direction, and the first orthographic projection is located between the orthographic projection of the adjacent first signal line on the substrate and the orthographic projection of the second signal line on the substrate.

11. The array substrate according to claim 10, wherein the first signal line and the second signal line are located in different film layers;
the first signal line is a scanning signal line and the second signal line is a light emission control signal line; and
the driving unit comprises a threshold compensation transistor electrically connected to the first signal line.

12. The array substrate according to claim 9, wherein the first signal line comprises a first extension portion and a first bent portion connected to each other, an orthographic projection of the first bent portion on the substrate being located on one side of the first orthographic projection, and the orthographic projection of the first bent portion on the substrate being configured to protrude in a direction away from the first orthographic projection.

13. The array substrate according to claim 12, wherein the driving device layer further comprises a third signal line, wherein an orthographic projection of the third signal line on the substrate is located on a side, which faces away from the first orthographic projection, of the orthographic projection of the first signal line on the substrate, and the third signal line comprises a second extension portion and a second bent portion connected to each other, an orthographic projection of the second bent portion on the substrate being located on a side, which faces away from the first orthographic projection, of the orthographic projection of the first bent portion on the substrate, and the orthographic projection of the second bent portion on the substrate being configured to protrude in the direction away from the first orthographic projection;
an orthographic projection of the second extension portion on the substrate is disposed parallel to an orthographic projection of the first extension portion on the substrate, or the
orthographic projection of the first bent portion on the substrate is disposed equidistantly from the orthographic projection of the second bent portion on the substrate.

14. The array substrate according to claim 13, wherein the third signal line and the first signal line are located in different film layers;
the third signal line and the second signal line are located in the same film layer; and
the driving unit comprises a data write transistor to which the third signal line is electrically connected.

15. An array substrate, comprising:
a substrate; and
a driving device layer disposed on one side of the substrate, the driving device layer comprising a first signal line and a second signal line, wherein an orthographic projection of the first signal line on the substrate and an orthographic projection of the second signal line on the substrate are both configured to extend in a first direction, and the orthographic projection of the first signal line on the substrate and the orthographic projection of the second signal line on the substrate are disposed side by side in a second direction which intersects the first direction;
wherein the array substrate comprises at least a light-transmitting area, an orthographic projection of the light-transmitting area on the substrate being defined as a first orthographic projection located between the orthographic projection of the first signal line on the substrate and the orthographic projection of the second signal line on the substrate.

16. The array substrate according to claim 15, wherein the first signal line is a scanning signal line and the second signal line is a light emission control signal line.

17. The array substrate according to claim 15, wherein the driving device layer further comprises a driving unit, the first signal line and the second signal line are electrically connected to the same driving unit, and the first orthographic projection is located between orthographic projections, on the substrate, of the first signal line and the second signal line which are electrically connected to the same driving unit; and
the array substrate comprises a plurality of the light-transmitting areas, each first orthographic projection being located between the corresponding orthographic projections, on the substrate, of the first signal line and the second signal line which are electrically connected to the same driving unit.

18. The array substrate according to claim 15, wherein the first signal line comprises a first extension portion and a first bent portion connected to each other, an orthographic projection of the first bent portion on the substrate being located on one side of the first orthographic projection in the second direction, and the orthographic projection of the first bent portion on the substrate being configured to protrude in a direction away from the first orthographic projection.

19. The array substrate according to claim 18, wherein the driving device layer further comprises a third signal line, wherein an orthographic projection of the third signal line on the substrate is located on a side, which faces away from the first orthographic projection, of the orthographic projection of the first signal line on the substrate, and the third signal line comprises a second extension portion and a second bent portion connected to each other, an orthographic projection of the second bent portion on the substrate being located on a side, which faces away from the first orthographic projection, of the orthographic projection of the first bent portion on the substrate, and the orthographic projection of the second bent portion on the substrate being configured to protrude in the direction away from the first orthographic projection.

20. A display panel, comprising:
an array substrate, comprising:
a substrate; and
a driving device layer disposed on a side of the substrate, the driving device layer comprising a plurality of driving units,
wherein the array substrate has at least a light-transmitting area, an orthographic projection of the light-transmitting area on the substrate being defined as a first orthographic projection located between orthographic projections of two of the driving units on the substrate,
wherein the display panel further comprises a functional layer located on a side of the driving device layer facing away from the substrate, one or more light-transmitting holes being provided in the functional layer, and an orthographic projection of the light-transmitting hole on the substrate at least partially overlapping with the orthographic projection of the corresponding light-transmitting area on the substrate.
